(19) United States
(12) Patent Application Publication
(10) Pub. No.: US 2023/0044473 A1
(43) Pub. Date: Feb. 9, 2023

(54) DOUBLE-SIDED FLEXIBLE CIRCUIT BOARD

(71) Applicant: CHIPBOND TECHNOLOGY CORPORATION, Hsinchu (TW)

(72) Inventors: Yin-Chen Lin, Miaoli County (TW); Hui-Yu Huang, Hsinchu City (TW); Chih-Ming Peng, Taichung City (TW); Chun-Te Lee, Hsinchu County (TW)

(21) Appl. No.: 17/837,145

(22) Filed: Jun. 10, 2022

(30) Foreign Application Priority Data
Aug. 9, 2021 (TW) 110129351

(51) Int. Cl. H05K 1/02; H05K 1/11

(52) U.S. Cl. CPC H05K 1/0277; H05K 1/0237; H05K 1/115; H05K 1/0268; H05K 2201/10507

(57) ABSTRACT

A double-sided flexible circuit board includes a flexible substrate, a first circuit layer, a second circuit layer, an insulating protection layer and a plurality of through circuit lines. The first and second circuit layers are located on a top surface and a bottom surface of the flexible substrate, respectively. The insulating protection layer covers a supporting line of the second circuit layer such that the supporting line is located between the flexible substrate and the insulating protection layer. The insulating protection layer can provide electrical insulation to the supporting line of the second circuit layer to avoid short circuit conditions of the double-sided flexible circuit board during test.

### FIELD OF THE INVENTION

This invention relates to a flexible circuit board, and more particularly to a double-sided flexible circuit board.

### BACKGROUND OF THE INVENTION

The demand of flexible and small size circuit board is growing because lightweight and thin electronic products become more and more popular over the past few years. Chip and circuit lines are usually disposed on the same surface of flexible circuit board for signal transmission, however, double-sided flexible circuit board having chip and circuit lines disposed on different surfaces may be desired owing to particular configuration of some electronic products. Through circuit lines passing through two surfaces of the double-sided flexible circuit board are required for electrically connection between two circuit layers located on the two different surfaces respectively. If a test platform where the double-sided flexible circuit board is placed on during test is contaminated by metal, test signal may be transmitted to the test platform via the top circuit layer, the through circuit lines and the bottom circuit layer to create a short-circuit path to damage the double-sided flexible circuit board.

### SUMMARY

One object of the present invention is to provide an insulating protection layer to cover a supporting line of a second circuit layer, the insulating protection layer provides electrical insulation between the supporting line and test apparatus to prevent short circuit conditions of a double-sided flexible circuit board from occurring during test.

A double-sided flexible circuit board of the present invention includes a flexible substrate, a first circuit layer, a second circuit layer, an insulating protection layer and a plurality of through circuit lines. The flexible substrate has a top surface, a bottom surface and a plurality of through holes which pass through the top and bottom surfaces. A chip mounting area, a transmission line disposing area and a test line disposing area are defined on the top surface, a chip is configured to be mounted on the chip mounting area, the transmission line disposing area is located between the chip mounting area and the test line disposing area. A test line supporting area corresponding to the test line disposing area is defined on the bottom surface. The first circuit layer is disposed on the top surface and includes an inner lead, a top transmission line and a test line. The inner lead is located on the chip mounting area, the top transmission line is electrically connected to the inner lead and located on the transmission line disposing area, the test line is electrically connected to the top transmission line and located on the test line disposing area. The second circuit layer is disposed on the bottom surface and includes a bottom transmission line and a supporting line. The supporting line is electrically connected to the bottom transmission line, located on the test line supporting area and under the test line. The insulating protection layer is located on the bottom surface and covers the supporting line of the second circuit layer to allow the supporting line to be located between the flexible substrate and the insulating protection layer. Each of the through circuit lines is disposed in one of the through holes, both ends of each of the through circuit lines are electrically connected to the first and second circuit layers respectively.

The insulating protection layer of the present invention can provide electrical insulation to the supporting line of the second circuit layer, consequently, the double-sided flexible circuit board can be protected from short circuit during test.

### DESCRIPTION OF THE DRAWINGS

FIG. 1 is a top-view diagram illustrating a double-sided flexible circuit board in accordance with one embodiment of the present invention.

FIG. 2 is a bottom view diagram illustrating the double-sided flexible circuit board in accordance with one embodiment of the present invention.

FIG. 3 is a cross-section view diagram illustrating the double-sided flexible circuit board in accordance with one embodiment of the present invention.

FIG. 4 is a partial enlarged top-view diagram illustrating the double-sided flexible circuit board in accordance with one embodiment of the present invention.

FIG. 5 is a cross-section view diagram illustrating the double-sided flexible circuit board during test in accordance with one embodiment of the present invention.

### DETAILED DESCRIPTION OF THE INVENTION

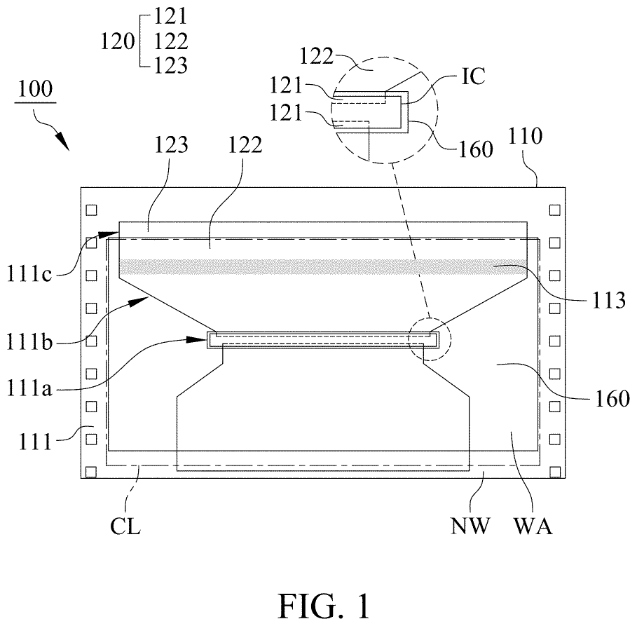

FIGS. 1 to 3 are respectively top view diagram, bottom view diagram and cross-section view diagram showing a double-sided flexible circuit board 100 in accordance with one embodiment of the present invention. The double-sided flexible circuit board 100 includes a flexible substrate 110, a first circuit layer 120, a second circuit layer 130, an insulating protection layer 140, a plurality of through circuit lines 150, a first solder resist layer 160 and a second solder resist layer 170.

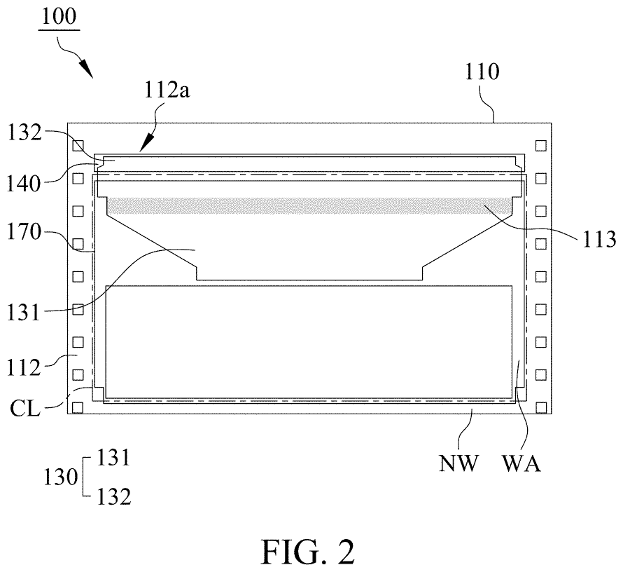

The flexible substrate 110 is made of polymer material having excellent electric insulation, stability, chemical resistance and mechanical behavior, such as polyimide. The flexible substrate 110 includes a top surface 111, a bottom surface 112 and a plurality of through holes 113 which communicate with the top surface 111 and the bottom surface 112. The through holes 113 are very tiny in size and difficult to be shown on FIGS. 1 and 2, so the grey marked areas on FIGS. 1 and 2 are provided to represent the location of the through holes 113 on the flexible substrate 110. Referring to FIG. 1, a chip mounting area 111a, a transmission line disposing area 111b and a test line disposing area 111c are defined on the top surface 111 of the flexible substrate 110. The chip mounting area 111a is provided for the mounting of a chip IC, the test line disposing area 111c is adjacent to the edge of the double-sided flexible circuit board 100, and the transmission line disposing area 111b is located between the chip mounting area 111a and the test line disposing area 111c. With reference to FIG. 2, a test line supporting area 112a is defined on the bottom surface 112 of the flexible substrate 110 according to the profile of the test line disposing area 111c, for this reason, the test line supporting area 112a is also adjacent to the edge of the double-sided flexible circuit board 100.

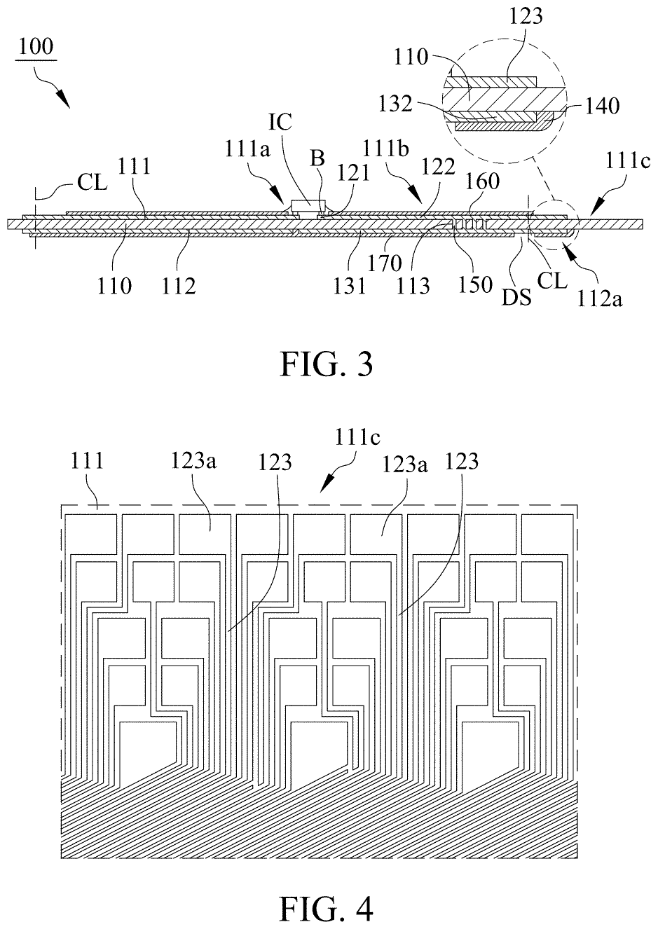

With reference to FIGS. 1 and 3, the first circuit layer 120 is disposed on the top surface 111 of the flexible substrate 110 and its pattern is formed by etching a copper layer which is plated or laminated on the top surface 111. In this embodiment, the first circuit layer 120 includes an inner lead 121, a top transmission line 122 and a test line 123. The inner lead 121 is located on the chip mounting area 111a and eutectic bonded to a plurality of bumps B of the chip IC. The top transmission line 122 is located on the transmission line disposing area 111b and electrically connected to the inner lead 121, and the top transmission line 122 is provided for transmitting signals generated by the chip IC to outside or transmitting signals to the chip IC from outside. The test line 123 is located on the test line disposing area 111c and electrically connected to the top transmission line 122, the test line 123 is provided for contacting of probe during electrical test of the first circuit layer 120 and the second circuit layer 130. The first circuit layer 120 is simplified into a block in FIG. 1, and in practice, it includes a plurality of tiny circuit lines. With reference to FIGS. 1 and 4, the test line 123 of the first circuit layer 120 preferably includes a test pad 123a which is wider than other circuit lines and provided for contacting of test probe in electrical test of the first circuit layer 120 and the second circuit layer 130.

With reference to FIGS. 1 and 3, the first solder resist layer 160 is located on the transmission line disposing area 111b of the top surface 111 to cover the top transmission line 122 of the first circuit layer 120, but the first solder resist layer 160 does not cover the inner lead 121 and the test line 123 of the first circuit layer 120. A solder resist ink is screen-printed on the transmission line disposing area 111b and then baked to become the first solder resist layer 160 which is used to protect the top transmission line 122 from heat damage.

With reference to FIGS. 2 and 3, the second circuit layer 130 is disposed on the bottom surface 112 of the flexible substrate 110 and it is formed by etching a copper layer which is plated or laminated on the bottom surface 112. In this embodiment, the second circuit layer 130 includes a bottom transmission line 131 and a supporting line 132, the bottom transmission line 131 is located under the top transmission line 122, the supporting line 132 is located on the test line supporting area 112a and under the test line 123, and the supporting line 132 is electrically connected to the bottom transmission line 131. In FIG. 2, the second circuit layer 130 located on lower part of the bottom surface 112 includes a plurality of dummy leads.

With reference to FIGS. 2 and 3, the second solder resist layer 170 is located on the bottom surface 112 of the flexible substrate 110 and covers the bottom transmission line 131 of the second circuit layer 130. Preferably, a solder resist ink is screen-printed on the bottom transmission line 131 and the dummy leads of the second circuit layer 130 and baked to become the second solder resist layer 170. The second solder resist layer 170 is provided to protect the bottom transmission line 131 from heat damage.

With reference to FIGS. 2 and 3, the insulating protection layer 140 is located on the bottom surface 112 of the flexible substrate 110 and covers the supporting line 132 of the second circuit layer 130, such that the supporting line 132 is located between the flexible substrate 110 and the insulating protection layer 140. Preferably, a solder resist ink is screen-printed on the supporting line 132 and then baked to become the insulating protection layer 140 which can provide electrical insulation between the supporting line 132 and external environment. In this embodiment, the insulating protection layer 140, the first solder resist layer 160 and the second solder resist layer 170 are made of the same solder resist ink, and in other embodiments, the insulating protection layer 140 may be made of electrically insulative polymer.

Referring to FIGS. 1 to 3, each of the through circuit lines 150 is disposed in one of the through holes 113, both ends of each of the through circuit lines 150 are electrically connected to the first circuit layer 120 and the second circuit layer 130, respectively. The through circuit lines 150 are provided for electrical connection between the first circuit layer 120 and the second circuit layer 130, consequently, signal transmission between the first circuit layer 120 and the second circuit layer 130 is available using the through circuit lines 150.

With reference to FIG. 3, a space DS existing between the second solder resist layer 170 and the insulating protection layer 140 is provided for exposing a part of the bottom transmission line 131, and the bottom transmission line 131 exposed through the space DS is an outer lead which is provided for electrically connection between the double-sided flexible circuit board 100 and other electronic device, such as glass substrate or control circuit board. Furthermore, the outer lead is located on the bottom surface 112 different to the chip IC located on the top surface 111 so the double-sided flexible circuit board 100 can be used flexibly.

With reference to FIGS. 1 to 3, a cutting line CL is defined on the flexible substrate 110 in this embodiment. The area enclosed by the cutting line CL is defined as a working area WA, and the other area outside the cutting line CL is defined as a nonworking area NW. The flexible substrate 110 can be cut along the cutting line CL in a cutting process such that the working area WA can be separated from the flexible substrate 110 to become an integrated circuit. The inner lead 121 and the top transmission line 122 of the first circuit layer 120 and the bottom transmission line 131 of the second circuit layer 130 are located within the working area WA, and the test line 123 of the first circuit layer 120 and the supporting line 132 of the second circuit layer 130 are located within the nonworking area NW.

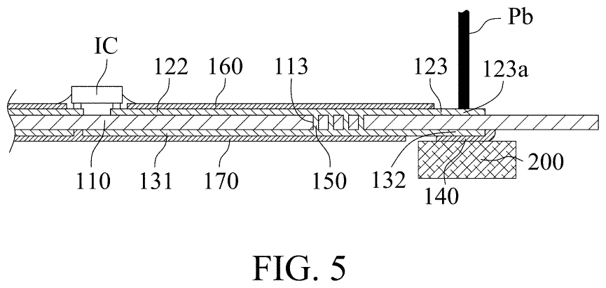

With reference to FIG. 5, the double-sided flexible circuit board 100 is placed on a push plate 200 as a test probe Pb is moved to contact the test pad 123a of the test line 123. The push plate 200 is used to support the double-sided flexible circuit board 100 such that the test probe Pb can reliably contact the test pad 123 during test. Meanwhile, the push plate 200 contacts the insulating protection layer 140, not contact the second circuit layer 130 directly, thereby reducing short circuit caused by metal contamination on the push plate 200 during test.

In the present invention, the insulating protection layer 140 can provide electrical insulation to the supporting line 132 of the second circuit layer 130 so as to protect the double-sided flexible circuit board 100 from short circuit conditions during test.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

What is claimed is:

1. A double-sided flexible circuit board comprising:
a flexible substrate including a top surface, a bottom surface and a plurality of through holes, the plurality of through holes are configured to communicate the top and bottom surfaces, a chip mounting area, a transmission line disposing area and a test line disposing area are defined on the top surface, the chip mounting area is configured for mounting of a chip, the transmission line disposing area is located between the chip mounting area and the test line disposing area, a test line supporting area is defined on the bottom surface according to a profile of the test line disposing area;
a first circuit layer disposed on the top surface and including an inner lead, a top transmission line and a test line, the inner lead is located on the chip mounting area, the top transmission line is electrically connected to the inner lead and located on the transmission line disposing area, the test line is electrically connected to the top transmission line and located on the test line disposing area;
a second circuit layer disposed on the bottom surface and including a bottom transmission line and a supporting line, the supporting line is electrically connected to the bottom transmission line, located on the test line supporting line and under the test line;
an insulating protection layer located on the bottom surface, the insulating protection layer is configured to cover the supporting line of the second circuit layer such that the supporting line is located between the flexible substrate and the insulating protection layer; and
a plurality of through circuit lines each disposed in one of the plurality of through holes, one end of each of the plurality of through circuit lines is electrically connected to the first circuit layer and the other end of each of the plurality of through circuit lines is electrically connected to the second circuit layer.

2. The double-sided flexible circuit board in accordance with claim 1 further comprising a first solder resist layer located on the top surface, wherein the first solder resist layer is configured to cover the top transmission line of the first circuit layer and not cover the inner lead and the test line of the first circuit layer.

3. The double-sided flexible circuit board in accordance with claim 1 further comprising a second solder resist layer located on the bottom surface, wherein the second solder resist layer is configured to cover the bottom transmission line of the second circuit layer.

4. The double-sided flexible circuit board in accordance with claim 3, wherein there is a space between the second solder resist layer and the insulating protection layer, the space is configured to expose a part of the bottom transmission line, and the bottom transmission line exposed from the space is an outer lead.

5. The double-sided flexible circuit board in accordance with claim 1, wherein a cutting line is defined on the flexible substrate, an area enclosed by the cutting line is defined as a working area and an area outside the cutting line is defined as a nonworking area, the flexible substrate is configured to be cut along the cutting line during a cutting process, the working area is configured to be separated from the flexible substrate as an integrated circuit, the test line of the first circuit layer and the supporting line of the second circuit layer are located on the nonworking area.

6. The double-sided flexible circuit board in accordance with claim 5, wherein the inner lead and the top transmission line of the first circuit layer and the bottom transmission line of the second circuit layer are located on the working area.

7. The double-sided flexible circuit board in accordance with claim 1, wherein the test line of the first circuit layer includes a test pad which is configured for contacting of a test probe.

8. The double-sided flexible circuit board in accordance with claim 7, wherein the double-sided flexible circuit board is configured to be placed on a push plate and the insulating protection layer is configured to contact the push plate as the test probe contacts the test pad.
